(19) United States
(12) Patent Application Publication
(10) Pub. No.: US 2021/0327690 A1
(43) Pub. Date: Oct. 21, 2021

(54) METHOD FOR GENERATING AND PROCESSING A UNIFORM HIGH DENSITY PLASMA SHEET

(71) Applicant: Dyson Technology Limited, Wiltshire (GB)

(72) Inventors: Michael John THWAITES, Hook (GB); Peter John HOCKLEY, Lymington (GB)

(73) Assignee: Dyson Technology Limited, Wiltshire (GB)

(21) Appl. No.: 17/270,362

(22) PCT Filed: Aug. 21, 2019
(86) PCT No.: PCT/GB2019/052345

§ 371 Date: Feb. 22, 2021

(30) Foreign Application Priority Data
Aug. 23, 2018 (GB) 1813730.7

(51) Int. Cl. H01J 37/34; H01J 37/32; C23C 14/35; C23C 16/50

(52) U.S. Cl. CPC H01J 37/34; H01J 37/3211; H01J 2237/332; C23C 16/50; H01J 37/32697; C23C 14/351

(57) ABSTRACT

A method of generating and processing a uniform high density plasma sheet. The method comprising generating a plasma within a chamber using plasma source; and within the same chamber containing and shaping the plasma using magnetic and/or electrostatic fields. The plasma is propagated as a uniform high density sheet within the chamber.

### REFERENCE TO RELATED APPLICATIONS

This application is a national stage application under 35 U.S.C. 371 of International Application No. PCT/GB2019/052345, filed Aug. 21, 2019, which claims the priority of United Kingdom Application No. 1813730.7, filed Aug. 23, 2018, the entire contents of each of which are incorporated herein by reference.

### FIELD OF THE DISCLOSURE

The present disclosure relates to a method of generating and processing a plasma. More specifically, the present disclosure relates to a method of using a uniform sheet of high density plasma for depositing material on a substrate.

### BACKGROUND OF THE DISCLOSURE

High density plasmas are used in a wide range of industrial applications. For instance, such plasmas can be used in surface cleaning or preparation applications, etching applications, modifying surface structures or densities, and the deposition of thins films. Current methods for generating wide continuous sheets of high density plasma require plasma source with plasma chambers to generate working plasma (i.e. remote plasma sources). An example of such a plasma source is a multiple loop antenna arrangement that requires many antennas to create a wide working plasma. However, controlling the uniformity of the plasma generated by such multi-loop antenna systems can be difficult since the antennas need to be tuned to a precise equivalent power and frequency in order to achieve plasma uniformity. The multi loop antenna arrangement also consumes a large amount of power since multiple plasmas are generated.

### SUMMARY OF THE DISCLOSURE

The present disclosure relates to a method of generating and processing a uniform high density plasma sheet; the method comprising: generating a plasma within a chamber using plasma source; within the same chamber, containing and confining the plasma using magnetic and/or electrostatic fields such that plasma is propagated as a uniform high density sheet within the chamber; and within the same chamber, passing the plasma over a processing surface such that the plasma interacts with the processing surface.

The method of the present disclosure relies on an apparatus which is capable of forming and confining (i.e. shaping) a localised linear plasma formed in the chamber with a density greater than 10¹¹ cm⁻³. The plasma source may be said to be a localised plasma source located within the chamber. It has been surprisingly found that the high density plasma can be generated and shaped within the chamber without the plasma first being generated and drawn from a plasma chamber. In other words, the plasma of the present system is generated, maintained and shaped in a working space of the chamber, and is not generated in a separate, discrete, or non-integrated plasma chamber (usually referred to as a discharge tube), which is subsequently drawn into the working space of the chamber, as seen in the systems of the prior art. Thus, at least a part of the plasma source (i.e. antenna or housing) forms an integral or integrated element of the chamber, without the necessity of the housing or antenna being surrounded by a plasma chamber, or the housing itself being part of a plasma chamber.

It is unexpected that a plasma chamber is not necessary or a fundamental requirement for a linear high density plasma source, since it was well understood that a plasma chamber, (for example, a coil antenna surrounding a discharge tube or an antenna and housing within plasma chamber) was needed to generate and contain the plasma before it was shaped for processing in the chamber. In contrast, the present method relies on the high density plasma being generated and maintained in the gaseous medium of the chamber. It has been found that it is adequate to merely house or enclose the antenna itself within the chamber, thus greatly simplifying the design requirements of any related plasma processing apparatus using the method of the present disclosure.

The plasma source may comprise a length of antenna which extends through the chamber, and the magnetic and/or electrostatic fields contain and shape the plasma by propagating the plasma as a sheet in one orthogonal direction relative to the length of the antenna, and also confining the propagation of the plasma in the other orthogonal direction relative to the length of antenna, and the direction of the longitudinal axis of the antenna. One or more magnets may be used to shape and propagate the plasma across the chamber as a sheet or slab of thin plasma originating from a single linear source or single length of antenna. This is in contrast to methods used in inefficient large area plasma processing apparatus of the prior art where many antenna and magnets are arranged to create an unfocused plasma cloud or beam that can brought into contact with a process surface or target. A key feature of the present method is that the plasma is both magnetised at an appropriate level and that the magnetic field is orientated relative to the antenna such that the RF power applied by the antenna is propagated over a far greater spatial extent than is usual in other plasma generating systems.

The magnetic and/or electrostatic fields may have a magnetic field strength less than 20 Gauss. It has been surprisingly found that the plasma generated by the method of the present disclosure can be manipulated with a magnetic field strength as low as 4.8 Gauss, which is an order of magnitude less than the operating regions of the prior art (50-200 Gauss). The manipulation of the plasma by use of a much lower magnetic field strength allows the use of multiple plasma sources within a single chamber without detrimental or unintended cross plasma source interference, allowing multiple simultaneous plasma processes to be conducted in the same chamber.

In some embodiments, the method can be said to not include a plasma chamber. In other words, the plasma is not a remote plasma generated in a discrete plasma chamber. The benefits from removing the plasma chamber, or plasma chamber walls, means that one plasma source can generate a high density plasma with a large working width. In examples, the plasma can be generated along the entire length of an antenna within the processing chamber. In this instance, the plasma can be shaped by one or more magnets. Since there is a single plasma source, the plasma has a uniform density along the entire width of the one antenna, in contrast to the multi-antenna inductively coupled plasma of the prior art that requires multiple tuned antenna and magnets to carry out wide-area plasma processing.

In essence, the chamber comprises two walls, the antenna being connected to and extending between the two walls; and wherein a localised and linear plasma is generated along the entire length of the antenna, thus maximising the available working length of the antenna. The antenna and/or housing may abut or contact the walls of the chamber. The chamber adopts a generally box-shaped configuration. In examples, the housing and antenna can extend across a particular dimension of the chamber (i.e. extend from wall to wall) so that a high density plasma with a desired width which is as wide as the chamber can be generated. This plasma can then be drawn into a sheet in a direction that is orthogonal to the length of the antenna so as to produce a high density sheet of plasma that has uniformity of density in its entirety. The magnets also restrict the propagation of the plasma in two orthogonal directions relative to the length of antenna such that the sheet of plasma is propagated generally parallel with the processing surface. The sheet of plasma is thus created uniformly and with the maximum width available to the process chamber.

The antenna may be an RF-transmitter and the housing is at least partially transparent to RF radiation. In examples, the antenna(e) can be supplied with power from a radio frequency power supply system operating at a frequency between 1 MHz and 1 GHz; a frequency between 1 MHz and 100 MHz; a frequency between 10 MHz and 40 MHz; or at a frequency of approximately 13.56 MHz or multiples thereof. The housing can be formed such that parts or sections of the housing are opaque to the transmission of RF radiation, so that plasma is generated only in the sections where the housing is transparent. In examples, only a cross sectional side surface of the housing facing the one or more magnets is transparent to RF radiation, such that the RF radiation is transmitted only in the desired direction within the chamber to propagate the plasma.

The housing may have an internal volume that, in use, is maintained at a different pressure to the chamber. In this instance, the housing can be filled with a fluid that can cool the antenna sufficiently to improve the performance. In an alternative embodiment, the housing may be open to an atmosphere external to the chamber. In this embodiment, air from outside the chamber can be passed through the housing and over the antenna for cooling. The method can be run at higher power without requiring additional cooling equipment for the antenna. In this embodiment the antenna is also easily accessible for repair or replacement.

At least one of the one or more magnets may be placed within the chamber. The magnets can be positioned within the chamber in order to reduce the foot print of the chamber. Furthermore, the magnets can be manipulated within the space of the chamber to tune and direct the plasma formation. Thus, the plasma can be generated and shaped so that it is in the correct form as necessary for the chamber.

The distance between the antenna and the inner walls of the housing may not be constant along the length of the antenna. In other words, the antenna need not be a straight wire extending through the centre of the housing. The wire may for instance extend through the housing at an angle offset from the centreline of the housing such that one part or end of the antenna is closer to the internal wall of the housing relative to another part or end of the antenna. This would encourage plasma formation in a particular part of the processing chamber if required for certain applications. The position of the wire may not be fixed, such that the wire can move further away from the internal walls of the housing during operation of an apparatus if, for instance, intermittent plasma generation is required. In addition, the antenna may take a sinuous path through the internal volume of the housing creating plasma generation hot-spots which may be useful for certain applications. The antenna may be a helically wound wire. The provision of a wound wire allows for improved plasma generation.

The apparatus may be a deposition apparatus, the processing surface is a target and/or a deposition surface and the plasma sheet propagated in the plasma processing space in a direction which is generally parallel with the target and/or process surface.

### BRIEF DESCRIPTION OF THE FIGURES

A specific embodiment of the present invention will now be described by way of example with reference to the accompanying drawings.

FIG. 1 is a schematic cross section of a preferred plasma processing apparatus shown in the plasma generating system longitudinal cross section as applied to use in sputter apparatus, according to some embodiments;

FIG. 2 is the schematic cross section A-A′ shown in FIG. 1 viewed from the left hand side of FIG. 1, showing a transverse cross section of part of the plasma generating system, according to some embodiments; and

FIG. 3 is the schematic cross section B-B′ shown in FIG. 1 viewed from the bottom of FIG. 1, according to some embodiments.

### DETAILED DESCRIPTION OF THE DISCLOSURE

Details of methods, structures and devices according to the present disclosure will become apparent from the following description, with reference to the Figures.

The plasma processing apparatus 1 comprises a process chamber 2, a plasma generation system 3, a target assembly 4, a substrate assembly 5, a magnet 6 with associated power supply 7, and a process gas feed system 8.

The process chamber 2 in some embodiments is, in its simplest form, a sealed box which at least includes the plasma generation system 3, the target assembly 4 and the substrate assembly 5. In some embodiments, the plasma generation system 3 and the substrate assembly 5 are located proximate each other in the process chamber 2. Since the plasma generation system 3 and the substrate assembly 5 are in the same chamber space (i.e. no separate plasma chamber for generating a plasma), the process chamber 2 can be said to be divided into a localised plasma generation zone (including the plasma generation system 3), and a processing zone (including at least one of the target assembly 4 and/or the substrate assembly 5). In the specific assembly, the process chamber 2 also houses the magnet 6.

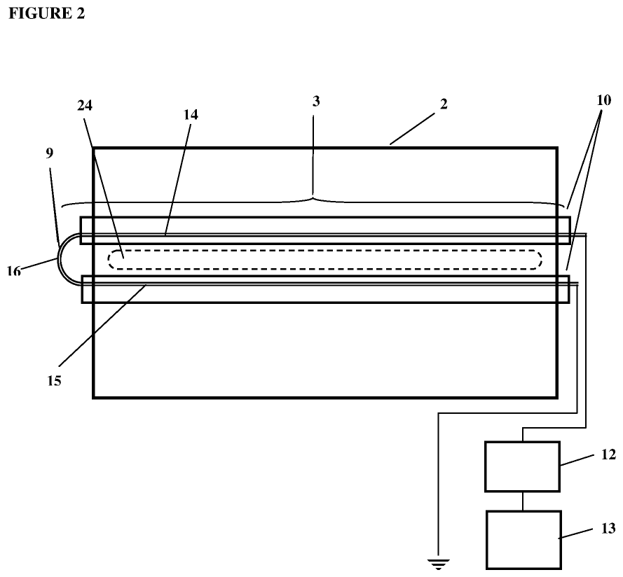

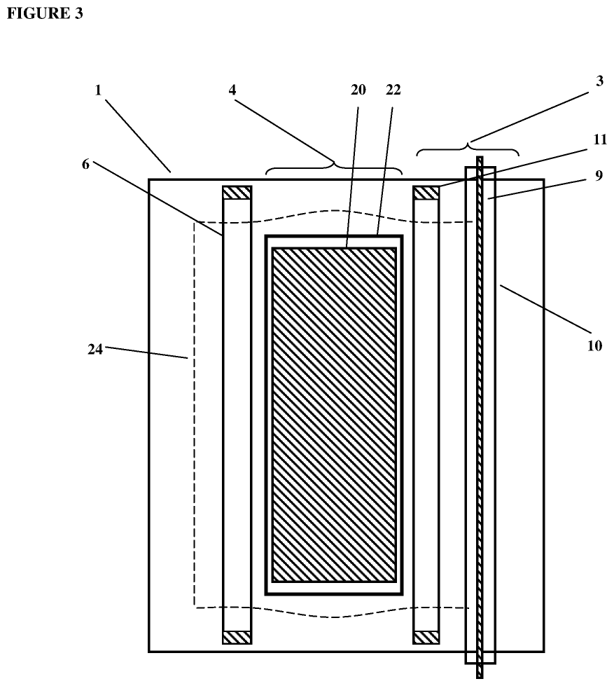

The plasma generation system 3 is located in in the process chamber 2 within the plasma generation zone and shown in more detail in FIGS. 2 and 3. The plasma generation system 3 comprises an antenna 9, a housing 10, and an electromagnet 11. The plasma generation system 3 is connected to an impedance matching network 12, and a signal generator 13. In contrast to prior art examples of process chambers, where plasmas are generated within contained plasma generation systems and then drawn out into the processing chamber, the plasma generation system 3 of the present disclosure resides within and is open to the same space of process chamber 2 where the plasma will be applied in processing of a target assembly 4 and/or substrate assembly 5. In other words, the plasma is generated locally in the atmosphere of the process chamber 2.

The antenna 9 is shown as a single looped wire which extends through the process chamber 2 in two straight sections 14,15 which are connected by a curved portion 16 outside of the process chamber 2. The straight sections 14,15 are offset in the process chamber 2 to induce plasma excitation in the region between the straight sections 14,15 of the antenna 9. The antenna 9 is constructed from shaped metallic tubing (e.g. copper tube), although alternate electrically conducting materials, for example brass or aluminium or graphite, could be used, as can differing cross sectional shapes, for example rods, strips, wire or a combined assemblies. In some embodiments, the antenna 9 is selected so that it can deliver RF frequency in the process chamber 2.

The housing 10 encloses and isolates the antenna 9 from the process chamber 2. The housing 10 comprises elongate tubes with a defined inner space or internal volume. The housing 10 extends through the process chamber 2 such that the tubes connect with the walls of the process chamber 2. The housing 10 is provided with suitable vacuum seals around the ends of the housing 10 and the walls of the process chamber 2, such that the internal volume is open to atmosphere at one or both ends as shown in FIGS. 2 and 3. The means of support and achieving vacuum seals and air cooling are omitted from the Figures for clarity.

The housing 10 is at least in part transparent to the radiation frequencies that are emitted from the antenna 9. The transparency of the housing 10 allows for the generation of plasma within the process chamber 2.

The housing 10 is a quartz tube, typically of wall thickness 2 to 3 mm. The housing 10 is of sufficient thickness such that the internal volume is open to atmospheric air, or a fluid flow can be passed through the internal volume to help with cooling the antenna. However, in some embodiments, the wall of the housing 10 may be of thinner and as such unable to support a substantial pressure differential between the process chamber 2 and the internal volume of the housing 10. In some embodiments, the housing 10 may need to be evacuated to balance the differences in pressure within the process chamber 2 and within the internal volume of the housing. It would be understood that a vacuum pumping system would need to be fitted or attached to the housing 10 to evacuate the internal volume in which the antenna 9 resides to a pressure that also suppresses plasma generation within the internal volume of the housing 10 rather than generating plasma within the process chamber 2.

The electromagnet 11 is positioned proximate the antenna 9 and the housing 10 and is capable of producing an axial magnetic field strength of from 4.8 Gauss up to 500 Gauss when powered by its associated power supply 11a. The electromagnet 11 provides a magnetic field within the process chamber 2 for propagating the plasma generated by the plasma generating system 3 from the plasma generation zone to and across the processing zone of the processing chamber 2.

The plasma generating system 3 also includes means to support, align and position the antenna 9, housing 10 and electromagnet 11 within the process chamber 2 to enable the tuning of the plasma generation and propagation. In addition the impedance matching network 12, and the signal generator 13 can be powered to specific frequencies for more efficient plasma generation.

The target assembly 4 resides within the processing zone of the processing chamber 2, and comprises a process chamber feedthrough 17 that feeds cooling water and electrical power to a mounting assembly 18, the target assembly 4 is capable of being water cooled and having a voltage applied to it from a power source 19 external to the process chamber 2. A target material 20 is fitted to the face of the mounting assembly 18 that faces the substrate assembly 5, ensuring good electrical and thermal contact by well-known means, for example bonding with silver loaded epoxy. Additionally in order to prevent sputtering of the mounting assembly 18 a shield 21 that is electrically grounded is provided around this item, allowing only the target material 19 to be directly exposed to the plasma.

The substrate assembly 5 essentially provides a means to position and hold a one or more substrate(s) 22 that are to be coated within the process chamber 2. The substrate assembly 5 may be water cooled or include heaters to control the substrates 22 temperature, be capable of having a voltage applied to it to assist control of deposited film properties, include means of rotating and/or tilting the substrates 22 to improve coating thickness uniformity, and itself be capable of being moved and/or rotated within the process chamber 2. A moveable shutter assembly 23 is provided such that in the ‘closed’ position target sputtering can take place without coating the substrates 22. The moveable shutter assembly 23 may be replaced with a fixed set of shields that define a coating aperture under which the substrate assembly 5 is translated so as to coat the substrates 22. For an appropriate substrate type and material the substrate assembly 8 may not be required.

In some embodiments, the target assembly 4 and the substrate assembly 5 are positioned and arranged in two parallel planes within the process chamber 2. These planes are common with the extending direction of the antenna 9 and housing 10 through the process chamber 2.

In some embodiments of the target assembly 4, the target material 20 and mounting assembly 18 are constructed to be of circular or essentially circular, for example hexagonal, external cross section, preferably with means for rotating the target material or assembly about the central longitudinal axis of the mounting assembly. This might be preferred over the planar geometry of the above described embodiment in order, for example, to maximise the target material 20 lifetime by essentially providing an increased surface area to be sputtered. The single target material 20 may also be replaced by two or more differing target materials, such that with appropriately fast rotation, for example 100 rpm, a coating of material on the substrate 22 that is a composite mixture, alloy or compound of the differing individual materials may be formed. Alternatively the rotation might be used to allow the differing materials to be positioned sequentially and/or alternately in the position where they will be sputtered, thereby providing a basis for sequential deposition of different thin film materials onto the substrates 22. Partial and controlled rotational positioning of two or more differing target materials might also be used to vary the coating mixture during deposition to allow a variable composition thin film coating to be realised. Additionally, the target assembly 4 may be engineered to allow individual target materials to be separately electrically biased; this is of especial use in cases where one or more of the targets will be biased by RF power means and it is desired to prevent RF power induced low intensity plasma generation and sputtering of the other target materials that might contaminate the process. In some embodiments, the target assembly 4 may be separately electrically biased by pulsed DC & DC Bias.

In some embodiments of the target assembly 4, the target shield 21 is extended to cover the whole length of the target material 20 and mounting assembly 18 and includes apertures that thereby only allow the plasma to interact with and sputter the target materials 20 at those places, thereby limiting and defining the target regions to be sputtered. This embodiment is especially useful when combined with a target comprising several target materials 20 and means of rotation as previously described as it is able to reduce cross-contamination of the materials at the substrates.

The magnet 6 is placed proximate to the target assembly 4 and the substrate assembly 5 and inside the processing zone of the process chamber 2. The magnet 6 is arranged away from the plasma generation system 3 and can be said to be arranged opposite to the plasma generation system 3 relative to the target assembly 4 and the substrate assembly 5. The magnet 6 and electromagnet 11 can be powered by their respective power supplies 7 and 11a to produce a magnetic field of strength approximately of from 4.8 Gauss and up to 500 Gauss between them and across the process chamber 2.

The process gas feed system 8 comprises one or more gas inlets for one or more process gases or process gas mixtures, each gas flow being controllable for example using commercial mass flow controllers, and optionally including gas mixing manifolds and/or gas distribution systems within the vacuum chamber. In some embodiments, a single gas inlet is provided to the vacuum chamber, the process gas or gases then being distributed to all parts of the process chamber 2 by normal low pressure diffusion processes or directed pipework.

Within the scope of the described embodiments are changes which would not affect the use of plasma processing apparatus 1. For instance the magnet 6 and electromagnet 11 may be exchanged, supplemented or even replaced by other magnetic means, for example additional permanent or electromagnets, in order to better control and guide the plasma. This may be required, for example, when a ferromagnetic target material is to be sputtered and additional field shaping is necessary to prevent the plasma being directed to the target assembly and thereby extinguished. As a further example, although most RF power systems used for plasma processing operate at 13.56 MHz, this being the frequency allocated for industrial use and thereby less prone to causing interference with other radio frequency users and so simpler to implement, alternate radio frequencies, for example 40 MHz or harmonics of 13.56 MHz, may be used to power the antenna 9 or power the target assembly 4 with appropriate RF shielding and suppression.

In some embodiments of the plasma generation system 3, the housing 10 is constructed from an assembly of materials. The housing 10 may include multiple tubes, for example of 2 to 3 mm thick quartz, placed side by side to enclose a multi-turn antenna 9. The housing 10 may be constructed to contain the antenna 9 at atmospheric pressure such that it may be readily cooled using simple air flow, thereby allowing the plasma generation system 3 to operate at higher RF powers than would otherwise be the case.

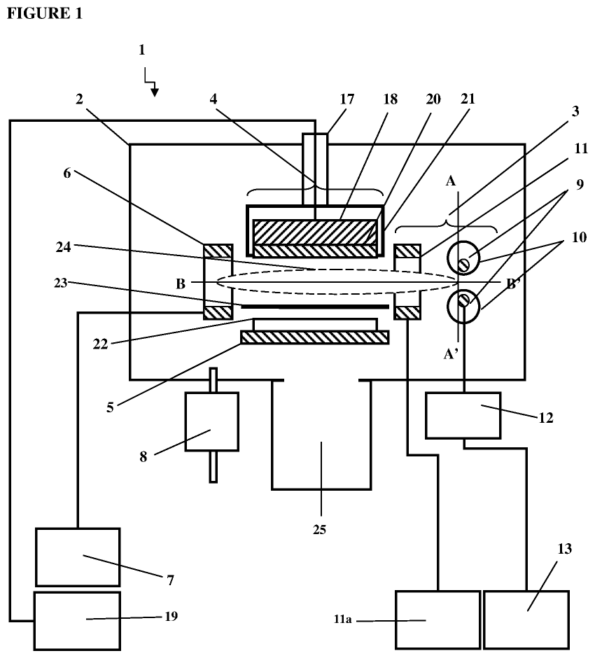

In use, the plasma processing apparatus 1 generates and propagates a uniform plasma sheet 24 within the process chamber 2, without the need for a separate or enclosed plasma chamber. An example of the operation of the above example system will now be described with reference to FIG. 1.

The RF antenna 9 is connected to and powered by the impedance matching network 12 and a 13.56 MHz RF generator 13 external to the process chamber 2 and a DC power supply 11a is electrically connected to the electromagnet 11 capable of producing an axial magnetic field strength of up to 500 Gauss.

The substrates 22 to be coated are loaded onto the substrate assembly 5 and the shutter assembly 23 is set to the closed position. The process chamber 2 is then pumped by a pumping system 25 to a vacuum pressure suitable for the process, for example less than 1×10-5 torr. The process gas feed system 8 is then used to flow at least one process gas, for example argon, into the process chamber. The flow rate and optionally the rate of vacuum pumping are adjusted to provide a suitable operating pressure for a sputter process, for example 3×10⁻³ torr. The magnet 6 and electromagnet 11 in conjunction with their respective power supplies 7 and 11ₐ are then used to produce a magnetic field of strength approximately 100 to 500 Gauss between them and across the process chamber 2. The magnetic ‘polarity’ of the magnet and electromagnet is identical (i.e. they attract).

A localised remote plasma 24 is generated in the process chamber 2 by applying RF power, for example 2 kW, from the generator 13 via the matching network 12 to the antenna 9. In combination with the magnetic field produced as described above, these result in a high density plasma produced across the chamber by the plasma generation system 3 and under the target assembly 4, as approximately indicated by the region 24 in FIGS. 1 and 3. The function of containing and shaping the plasma 24 is provided by the magnetic field. The localised plasma 24 is generated along the length of antenna 9 and housing 10 in the process chamber 2. The magnet 6 and electromagnet 11 supply a magnetic field across the chamber which interacts with the plasma 24. The magnet 6 and electromagnet 11 are arranged such that the plasma is excited and propagated in an orthogonal plane relative to the length of the antenna 9 through the process chamber 2. The orthogonal plane of the plasma 24 propagation runs substantially parallel to the two parallel planes of the target assembly 4 and the substrate assembly 5 within the process chamber 2. In addition, the magnetic field supplied by the magnet 6 and electromagnet 11 restricts the plasma excitation in other planes or directions relative to the length of the antenna 9 through the process chamber 2. In other words, the magnetic field supplied by the magnet 6 and electromagnet 11 restricts the plasma excitation in two orthogonal directions whilst propagating the plasma in a third orthogonal direction without the need for a plasma chamber to contain the plasma.

The DC power supply 19 is then used to apply a negative polarity voltage to the target assembly 4. This results in ions from the plasma 24 in the vicinity of the target assembly 4 being attracted to the target material 20 and, if the voltage is above the sputter threshold value for the target material 20 (typically in excess of 65 volts), sputtering of the target material 20 will occur. As the sputter rate for this example system is approximately proportional to the voltage above this threshold value, voltages of 400 volts or more will usually be applied; for very high rate applications higher voltages may be used, for example 1200 volts.

After an optional time delay to allow the surface of the target material 20 to clean and stabilise, for example 5 minutes, the shutter assembly 23 is set to the open position to expose the surface of substrates 22 facing the target assembly to the sputtered material, thereby coating the substrate surfaces with a film of the target material 20. After a time determined by the required film thickness and the deposition rate at the surface of the substrates 22, the shutter assembly 23 is set to the closed position and deposition onto the substrates 22 ceases.

### Example

A plasma generating system 1 containing a plasma generating system 3 was constructed substantially as shown in FIG. 1 and described above, omitting the sputter target, substrate and shutter assemblies. Both a planar permanent magnet and electromagnet of dimension equivalent to that of the antenna 9 were installed within the process chamber 2, their positions being changed as described below. The antenna 9 was constructed from 6 mm diameter copper tube, with two linear sections passing through the tubular housing 10, shaped so as to be offset from the enclosure central axis as shown and joined together with a further section of 6 mm copper tube and brass connectors at one end to form an extended approximately TT′ shaped loop. The housing 10 comprised two identical quartz tubes of wall thickness 3 mm passing across the process chamber 2 and through the walls of the chamber 2, being vacuum sealed at those points such that the housing 10 interior was open to atmosphere for cooling purposes and to avoid generating plasma within the housings 10.

The plasma generating system 3 produced an argon based plasma along the length of the antenna 9 and housing 10 within the process chamber 2. The plasma originating from the elongate antenna 9 and housing 10 was then guided and shaped as a uniform sheet 24 in one orthogonal plane relative to the length of the elongate antenna 9 and housing 10 to pass completely between the target material 20 and substrates 22. The plasma 24 therefore covered the whole target material surface 20, with no visible loss or non-uniformity of plasma density. It was noted that the presence of the target material 20 did not detrimentally affect the plasma 24, regardless of whether the target material 20 had a negative bias applied to it or not. Furthermore, the target assembly 4 did not substantially heat up, even in the absence of water cooling, despite being placed in proximity to the plasma 24. It was observed that the visible plasma 24 profile followed the expected magnetic field profile and expanded by about 60 mm in both cross sectional dimensions at the process chamber 2 mid-point from the electromagnet 11 before narrowing again to the magnet 6.

Hence an elongate plasma generating system 3 built according to the embodiment, or alternatives, has produced a high density plasma sheet 24, greater than 10¹² cm⁻³′ of cross sectional long dimension in excess of 400 mm and of uniformity at least adequate to allow uniform sputtering of a like dimensioned sputter target of width 125 mm.

The sputter deposition system was operated substantially according to the example description above, excepting that the deposition time was determined by the time for which the substrates were translated under the coating aperture. The following observations and results were obtained.

The process conditions were set as follows: an argon gas flow of 180 sccm, a resultant vacuum pressure in the process chamber of about 4×10⁻³ torr, 2.5 kW RF power applied to the RF antenna and the electromagnet 11 axial magnetic field at approximately 4.8 Gauss and the magnet 6 axial magnetic field at approximately 10 Gauss. This produced intense argon plasma of characteristic purple-blue colouration denoting the presence of a plasma density of between 10¹² and 10¹³ cm⁻³.

The disclosure can also be used in a reactive sputter process, that is a process in which a reactive gas or vapour is introduced via the gas feed system 8 to react with the sputtered target material 20 or materials and thereby deposit a compound thin film on the substrate 21. For example, oxygen gas can be introduced into the sputter process with any of the embodiments previously described in order to deposit oxide thin films, for example to deposit alumina by sputtering of an aluminium target in the presence of oxygen gas or silica by sputtering of a silicon target in the presence of oxygen gas.

The elongate plasma generation system 3 can operate independently of any sputter target allowing further application to be realised. Thus the above described elongate plasma generation system 3 may be used as a substrate cleaning, surface modification or etch tool with especial utility where large dimensioned substrates are to be processed at high throughput rates, for example in roll to roll (“web”) coating.

The elongate plasma generation system 3 could also be used as a ‘plasma assist’ tool for other coating processes, as is typically used in evaporative coating process tools.

The elongate plasma generation system 3 could also be applied to coating processes based on the technique of Plasma Enhanced Chemical Vapour Deposition (PECVD).

The disclosed elongate plasma generation system 3 is of particular utility in all these processes due to the innate ability to generate uniform high density plasma over very long lengths and widths, thereby allowing its use with large dimensioned substrates.

1. A method of generating and processing a uniform high density plasma sheet; the method comprising:
generating a plasma using a plasma source located within a chamber;
within the same chamber, containing and confining the plasma using at least one of magnetic fields or electrostatic fields such that plasma is propagated as a uniform high density sheet within the chamber; and
within the same chamber, passing the plasma over a processing surface such that the plasma interacts with the processing surface.

2. The method of claim 1, wherein the plasma source comprises a length of antenna which extends through the chamber, and the at least one of magnetic fields or electrostatic fields contain and shape the plasma by propagating the plasma as a sheet in one orthogonal direction relative to the length of the antenna, and also confining the propagation of the plasma in the other orthogonal direction relative to the length of antenna and the direction of the longitudinal axis of the antenna.

3. The method of claim 2, wherein the sheet of plasma is propagated such that it is parallel with the processing surface.

4. The method of claim 1, wherein the at least one of magnetic fields or electrostatic fields has a magnetic field strength less than 20 Gauss.

5. The method of claim 1, wherein the plasma source is a localised plasma source located within the chamber.

6. The method of claim 1, wherein the chamber comprises two walls, the antenna being connected to and extending between the two walls, and wherein a localised and linear plasma is generated along the entire length of the antenna.

7. The method of claim 1, wherein the antenna is an RF-transmitter and the antenna is enclosed in a housing which is at least partially transparent to RF radiation.

8. The method of claim 7, wherein the housing has an internal volume that, in use, is maintained at a different pressure to the chamber.

9. The method of claim 7, wherein the housing is open to an atmosphere external to the chamber.

10. The method of claim 1, wherein the plasma is not generated within a discrete plasma chamber.

11. The method of claim 1, wherein the at least one of the magnetic fields or the electrostatic fields has a magnetic field strength of 4.8 Gauss.

12. The method of claim 1, wherein the chamber is located within a deposition apparatus, the processing surface is at least one of a target or a deposition surface and the plasma sheet propagated in a plasma processing space in a direction which is parallel with the at least one of a target or a deposition surface.
